(19) United States
(12) Patent Application Publication
(10) Pub. No.: US 2025/0055247 A1
(43) Pub. Date: Feb. 13, 2025

(54) CAPACITIVE COUPLING FOR DRIVING CLOSED CHAMBER AMPLIFICATION LASER

(71) Applicant: SATIUS HOLDING, LLC., Highland, MD (US)

(72) Inventor: Charles ABRAHAM, Fulton, MD (US)

(21) Appl. No.: 18/594,996

(22) Filed: Mar. 4, 2024

Related U.S. Application Data
(63) Continuation-in-part of application No. 17/882,237, filed on Aug. 5, 2022.

(51) Int. Cl. H01S 3/091; H01S 3/00; H01S 3/0915

(52) U.S. Cl. CPC H01S 3/0912; H01S 3/005; H01S 3/0915

(57) ABSTRACT

Aspects of the present disclosure may address the problem of coupling an input signal to a high-power laser device, where the output impedance of the device providing the input signal and the laser device input impedance differ. A coupler according to aspects of the present disclosure may be a capacitive coupler that may include parallel concentric coils, which may be comprised of wire or metal plate coils, or parallel plates, which may, in turn, be connected in series with a variable capacitive element. According to a further aspect of the present disclosure, parallel concentric coils and/or parallel plates may be arranged in parallel, and the input signal to the capacitive coupler may be switched to one or the other. The switching may be automated, based on frequency content or amplitude of the input signal.

### CROSS-REFERENCE TO RELATED APPLICATIONS

The present application is a continuation-in-part of U.S. patent application Ser. No. 17/882,237, filed on Aug. 5, 2022, and incorporated by reference herein.

### FIELD

Various aspects of the present disclosure may relate to the use of capacitive means by which to couple signals for being amplified to drive a laser apparatus at high power levels.

### BACKGROUND

Lasers have many uses, and many more uses may be possible with the use of lasers that emit beams of increasing power. Such uses may include military defense, power transmission, long-distance communications, industrial applications, and the like. However, configuring lasers to generate sufficient power has been an issue.

In particular, one issue that has arisen is how to couple an input signal (or signals) to the laser. Many conventional matching elements or coupling schemes result in large power losses, thus decreasing the power-efficiency of the system, and hence the power of the laser output.

Therefore, it may be desirable to couple signals to lasers by using devices that result in lower power losses than with conventional matching elements or coupling schemes.

### SUMMARY

Various aspects of the present disclosure may relate to a driver coupling circuit based on parallel coils or plates with non-conductive, non-magnetic cores that may be used to perform impedance matching for driving a high-energy laser device. Such a high-energy laser device may be one equipped with a dedicated external power amplification stage that may need to be coupled to a pre-amplifier of an input signal. Alternatively, the high-energy laser device may be single integrated device in which the power amplification is part of the laser device itself, e.g., in the form of a closed-tube chamber amplification laser device.

### BRIEF DESCRIPTION OF THE DRAWINGS

Various aspects of this disclosure will now be described in detail in conjunction with the accompanying drawings, in which:

FIGS. 1A and 1B show examples of various aspects of the disclosure relating to the use of parallel coil capacitive coupling;

FIGS. 1C and 1D show examples of configurations of high-energy laser devices;

FIGS. 2A and 2B show examples of various aspects of the disclosure relating to the use of parallel plate capacitive coupling;

FIG. 3 shows an example of a system that incorporates switching between capacitances/impedances of different values;

FIG. 4 shows an example of a system that may incorporate parallel coil and parallel plate capacitive coupling, according to various aspects of the present disclosure;

FIG. 5 shows an example of a further capacitive element according to various aspects of the present disclosure; and

FIG. 6 shows an example of a parallel plate capacitive element according to various aspects of the present disclosure.

### DETAILED DESCRIPTION

Most RF or digital or analog driver circuits are designed for output with a 50Ω impedance (sometimes other impedance levels may be used, but they are generally standard values, such as 50Ω). As an example, Texas Instruments SN5545xB or SN7545xB drivers are designed with a 50Ω output impedance. See, e.g., Section 7.5 of Texas Instruments, SN5545xB, SN7545xB Dual-Peripheral Drivers for High-Current, High-Speed Switching, Revised January 2017, and incorporated by reference herein. Radio frequency (RF) power amplifiers are typically designed with an output impedance of 50Ω. This may work for most devices to be driven by such circuits, which typically are designed with a 50Ω input impedance. However, a laser device including an amplifier, e.g., a closed-tube amplification laser device, may have a much higher input impedance.

A high-power laser (for the purposes of this disclosure, a “high-power laser” should be understood as a laser device having an output power of greater than 10 kW (in many cases, more than 100 kW) and excluding laser diodes) may generally include, or have associated with it, an amplifier powerful enough to output a input signal that will result in the excitation of the gas, liquid, plasma, or other material contained in the laser device to achieve the high output power. This may generally be in the form of a tube-type amplifier and may be integrated as part of the laser device or may be a separate component feeding a signal to the laser device. In some cases, multiple stages of amplification may be used to obtain a sufficiently high-power driving signal.

A problem that arises is that the tube amplifier (or “amplification stage” if one considers multiple stages of high-power tube amplification to obtain the final high-power laser driver signal) may often have a higher input impedance value than an output impedance of an initial pre-amplifier, which may be used to amplify an input signal. While the pre-amplifier may have an output impedance on the order of, e.g., 50Ω, a tube amplifier used with/in a high-powered laser device may have an initial input impedance on the order of hundreds of ohms (and its steady-state input impedance may then drop to a much lower impedance, e.g., in a range from 0.1Ω to tens of ohms). Therefore, it may be advantageous to incorporate impedance matching circuitry/device(s) to couple the pre-amplification to the tube-based amplification, in order to avoid power loss/dissipation that may result from an impedance mismatch and thereby provide most or all of the signal power to amplification stage and thus to the laser device.

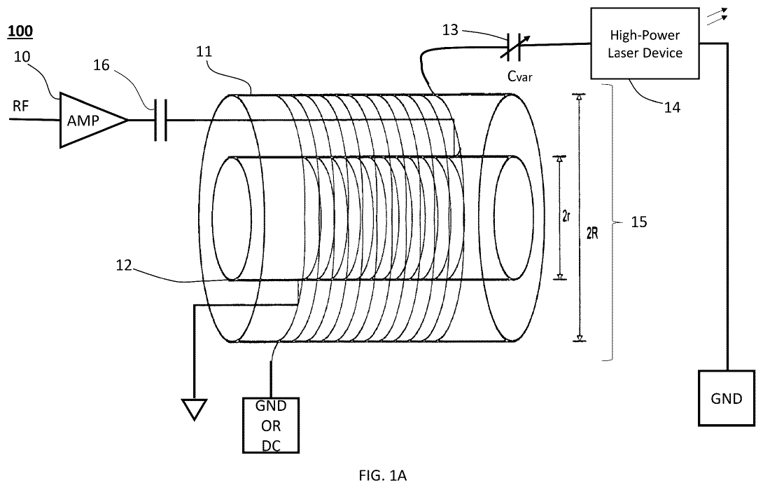

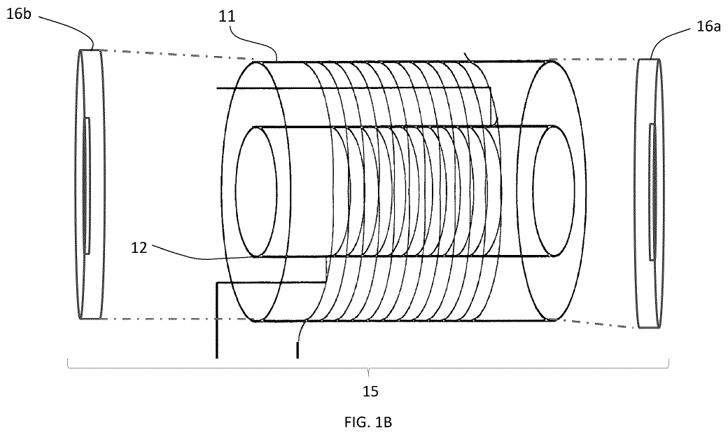

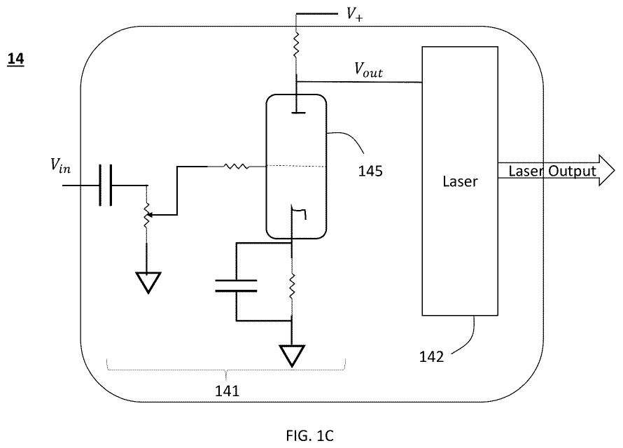

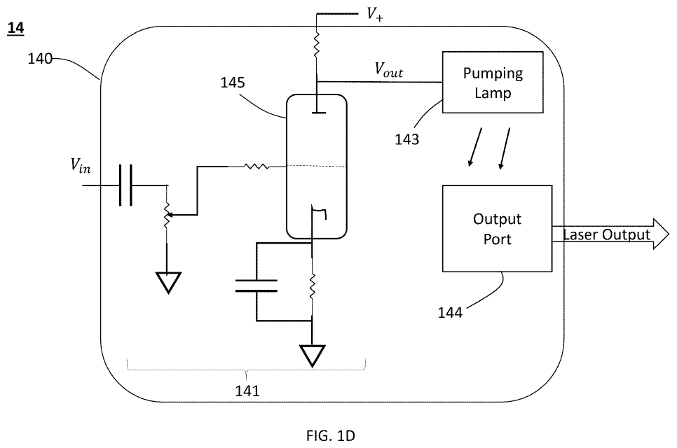

FIGS. 1A and 1B show examples relating to a first type of coupling system 100 according to various aspects of the present disclosure. As shown in FIG. 1A, a typical system 100 may involve coupling an input signal (shown as “RF” in the drawings to reflect a non-limiting example, but understood to refer to any type of analog or digital signal, which may include, for example, a radio frequency (RF) signal, a pulsed signal, a direct current (DC) or alternating current (AC) signal, or a modulated signal) to a high-power laser device 14. The input signal may be amplified by an amplifier 10, as a pre-amplification stage. The amplified input signal may then be provided as input to a concentric parallel coil capacitance 15, having inner 12 and outer 11 coils of respective radii r and R, with r<R; note that a DC blocking capacitor 16 may be provided between the amplifier and the parallel coil capacitance 15. The coils 11, 12 may be wound tightly around respective non-conductive, non-magnetic tubular cores, e.g., but not limited to one or more ceramic materials, such that there is substantially no space between adjacent turns of each coil 11, 12; the windings may comprise insulated wire, e.g., but not limited to, insulated copper, silver, or gold wire. The coils 11, 12 may be separated by air (“an air core”) or by some other dielectric material. According to one aspect of the present disclosure, the amplified input signal may be fed to inner coil 12, which may be connected to ground at its other end; inner coil 12 may be matched to the output impedance (e.g., 50Ω) of the amplifier 10 (in fact, in all examples below, the input impedance of the capacitive element may be matched to the output impedance of the device that feeds it). Outer coil 11 may be connected to ground or to a direct current (DC) source at one end, and the other end may be coupled to an input of a variable capacitor (Cᵥₐᵣ) 13, which may act as a tuning capacitor (note that according to other aspects of the present disclosure, this may be a fixed capacitor, which may also act as a tuning capacitor, or there may be both a fixed capacitor and a variable capacitor; in other examples, this capacitor may be omitted). The output of variable capacitor 13 may feed the high-power laser device 14, which may be also coupled to ground (and may also typically be coupled to a voltage source (not shown in FIGS. 1A and 1B)). Variable capacitor 13 may be manually or automatically adjusted to maximize output power from laser device 14; this may be done, for example, by monitoring the light energy output from laser device 14 or the output from the amplifier 10 and using a measured value as a feedback input to a user display or to a comparator that may compare the output measurement with a previous output measurement and may determine an adjustment to the variable capacitor 13 based on the comparison result (e.g., by controlling a mechanical adjuster, e.g., using a motor). Alternatively, this may be done by monitoring the amplified input signal energy using an energy and/or amplitude detector and using a measured value as a feedback input to a user display or employing a comparator (or other comparison device) that may compare a measured value with a previous measured value and may determine an adjustment to the variable capacitor 13 based on the comparison result.

Referring to FIG. 1B, in the case in which the capacitive coil structure 15 has an air core, some type of structure may be needed to maintain the inner 12 and outer 11 coils separated from each other. According to one aspect of the present disclosure one or two caps 16a, 16b may be fitted to the coils 11, 12 at one end or at both ends, where the cap(s) may be sufficiently supportive of the coils 11, 12 to maintain their distance from one another. In the case of using a single cap, that cap may need to fit sufficiently deeply onto and/or into the coils 11, 12 so as to be able to support the coils 11, 12 without the use of a second cap or other structure. The cap or caps 16a, 16b may be composed of a non-conductive, non-magnetic material, such as, but not limited to, a plastic or ceramic material. The cap or caps 16a, 16b need not fully cover the entire end of the coil structure 15; rather, there may be holes or other openings in the caps, which may permit the passage of wires for various couplings shown in FIG. 1A and/or for other purposes (e.g., dissipation of heat that may result from parasitic resistance and/or inductance).

Structures other than caps 16a, 16b, such as non-conductive, non-magnetic structural crosspieces (not shown), may be used to maintain separation between the coils 11, 12.

In the cases of caps 16a, 16b or other structures to maintain separation between coils 11, 12, the caps or other structures may be formed so as to permit water, air, or some other cooling medium to pass through between the coils. Additionally or alternatively, a cooling medium may be directed around the complete coil structure. Allowance of a cooling medium to pass through and/or around may be applicable to other capacitances and/or capacitive structures described herein, according to aspects of the present disclosure.

FIGS. 1C and 1D show conceptual examples of a high-power laser device 14 that may be used according to aspects of the present disclosure. The example of FIG. 1C shows a non-limiting example of a tube amplifier 141 receiving an input signal Vin from the capacitive coupling structure 15 (via the variable capacitor 13, if present) and feeding its amplified output signal Vₒᵤₜ to a high-power laser 142, which produces a laser output; note that a high-power laser is typically a laser apparatus using excitation of a liquid, gas, or plasma medium to achieve high-power lasing. Amplifier 141 may be a tube amplifier including a vacuum tube 145 having an anode, a cathode, and a grid. The example of FIG. 1D shows a tube amplifier 141 incorporated within a common tube 140 with laser components 143, 144; this may be an example of a closed-tube chamber amplification laser device. The tube may contain a liquid, such as liquid carbon dioxide, a mixture of exotic fluids, a gas, a plasma, or any other medium that may be excited to induce lasing. In the non-limiting example of FIG. 1D, the laser type may be that of a lamp-pumped laser, where the output signal from the tube amplifier 141 is used to drive a pumping lamp 143 that may be used to inject energy into the medium to cause lasing, and the resulting laser signal may be output via an output port 144, or alternatively, via a laser-transparent window in tube 140.

While FIGS. 1C and 1D show a single-stage tube amplifier 141, the amplifier is not limited to a single stage and is not limited to the circuit shown. Other amplifier designs, which may use different circuitry and may have more than one stage may be used. Such multi-stage amplifier designs may correspond to well-known amplifier designs that may include multiple vacuum tubes.

The capacitive structure 15 of FIGS. 1A and 1B may be useful for input signals of a frequency range up to about 150 MHz. However, above about 150 MHz, parasitic impedances (inductive and resistive) may generally begin to become substantially more inductive, resulting in lower capacitive coupling efficiency, increased power dissipation, and loss of impedance matching. Consequently, it may be useful to use a different structure for the capacitive structure for input signals above 150 MHz.

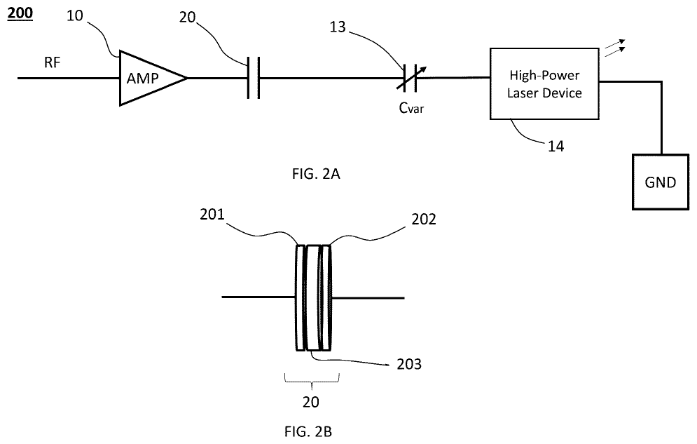

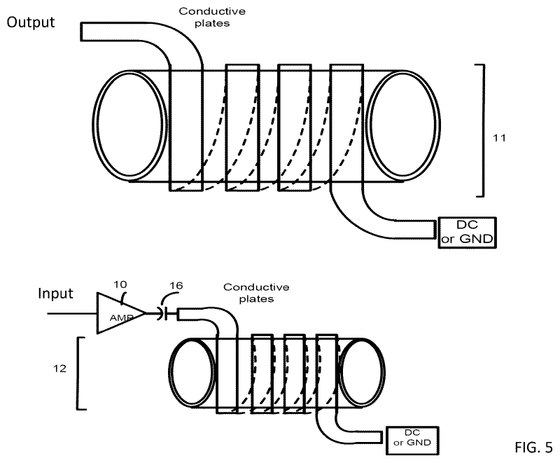

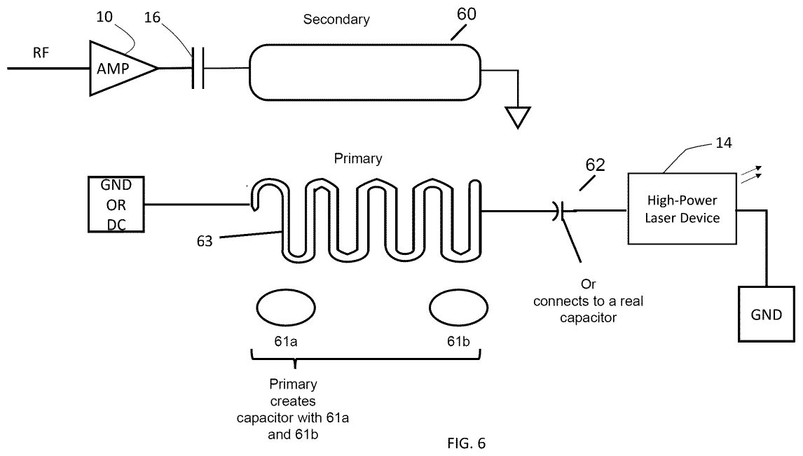

FIGS. 2A and 2B illustrate a first alternative capacitive coupling structure 200 according to further aspects of the present disclosure. Above 150 MHz, and in particular above 750 MHz, a parallel plate capacitive element 20 may be used instead of the concentric parallel coil capacitive element 15 (a further alternative, using wound plate coils is explained in conjunction with FIG. 5, which may be useful in the range between 150 MHz and 750 MHz; a further parallel plate structure is also discussed below in conjunction with FIG. 6). As shown in FIG. 2A, similar to FIG. 1A, the capacitive element 20 may be followed by a variable capacitor 13 that may be used to adjust and optimize the capacitive coupling, as discussed above. Parallel plate capacitive element 20 may be implemented as a parallel plate capacitor, as shown in FIG. 2B or FIG. 6. Parallel plates 201, 202, each have a contact to which to connect the parallel plate capacitor 20 in a system. The parallel plates 201, 202 may be separated by a dielectric 203, which may be air, ceramic, or some other dielectric material. The shapes and areas of the parallel plates 201, 202 may be selected, according to known principles of physics, to optimize coupling, e.g., based on the desired operating frequency band, to minimize spurious effects (e.g., parasitic resistance and/or inductance), etc.

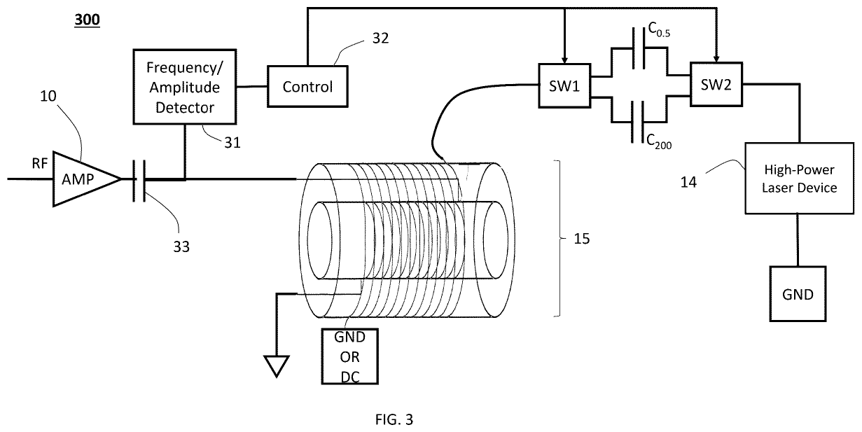

In the case of, for example, a high-power laser, there may be different states having different input impedances. For example (which should be understood as non-limiting), a high-power laser may have an initial start-up input impedance of 200Ω and a post-activation input impedance of 0.5Ω. As explained above in the general case, failure to match impedances may result in significant power loss. FIG. 3 shows a non-limiting example implementation of a system 300 with a coupler that switches between matching input impedances of 0.5Ω and 200Ω; again, these are just examples, and the input impedances may take other values. As in the previous case, an input signal may be amplified by an appropriate amplifier 10, which may be followed, optionally, by a DC blocking capacitor 33. The amplified output (following the blocking capacitor, if used) may then be fed to a parallel coil capacitive element 15, whose output may be switched between (capacitive) impedances C_{0.5} and C₂₀₀ designed to match the two input impedance states of high-power laser device 14. Switches SW1 and SW2 may be controlled such that the signal is routed through the appropriate one of the impedances. Control may be performed automatically, e.g., via frequency/amplitude detector 31 and control logic 32. Frequency/amplitude detector may detect a frequency of the (amplified) input signal, as well as an amplitude of the signal. Impedance mismatch may cause the amplitude to vary, and the control logic 32 may use at least one comparator (for example) to determine whether the amplitude indicates that the impedance into the laser device 14 is not being matched by the impedance presently switched into the system and may generate a control signal that may be fed to the switches SW1 and SW2 to select use of the other impedance.

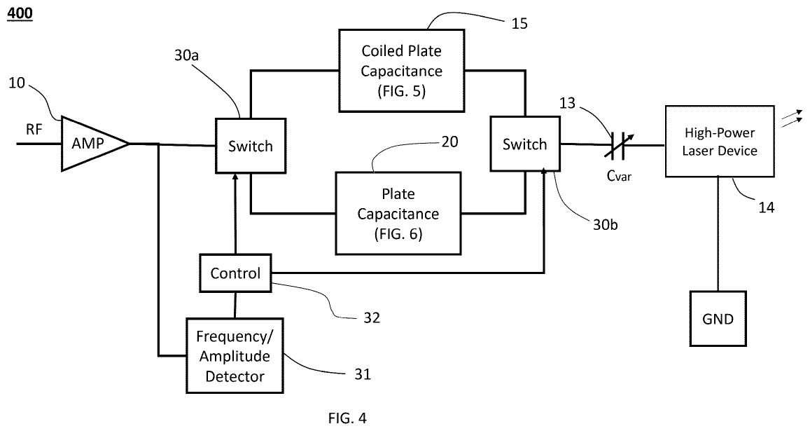

In some scenarios, the frequency of signals to be coupled to the high-power laser device 14 may not be the same at all times and may vary beyond the ranges at which the respective structures of the capacitive elements of FIGS. 1A and 2A are better. In view of this, FIG. 4 presents a system 400 in which both types of capacitive components 15, 20 are incorporated. The amplified input signal from the output of amplifier 10 (which may be followed by a DC blocking capacitor (not shown)) may be input to a switch 30a. Switch 30a may be a manual switch or may be controlled automatically. The implementation may depend on whether it is anticipated that the input frequency may vary suddenly or may remain within one of the ranges of the two different capacitive structures 15, 20 for times during which a person would be able to manually operate switch 30a to correctly route the input to the correct structure (and similarly operate switch 30b to route the output from the correct structure). If it is anticipated that the input signal frequency may vary quickly and/or frequently, switches 30a, 30b may incorporate an electrical input to control switching between the inputs to and outputs from capacitive structures 15, 20. This may be implemented, for example, by coupling a frequency/amplitude detector 31 to the input or output signal of the amplifier 10. Frequency/amplitude detector 31 may detect a frequency or frequency and amplitude of the input signal and may automatically generate a control signal to send to switches 30a, 30b to determine how the input signal should be routed and from which capacitive structure 15, 20 to obtain the output signal. Otherwise, the remainder of the apparatus of FIG. 3 may comprise the variable capacitor 13 and high-power laser device 14 as in FIGS. 1A and 2A. Note that, according to a further aspect of the present disclosure, it may also be possible to use a fixed capacitor to provide a 0.5Ω impedance at the high-power laser device input all the time, rather than a variable capacitor, and the capacitive structures 15, 20 may be designed to provide any additional impedance matching.

In some examples, high-power laser device 14 may be used for optical frequency communications, e.g., via free space. In this use case, the input signal to be coupled to the diode 14 may be a relatively high-frequency signal, e.g., with one or more carrier frequencies exceeding 150 MHz. In this case, to obtain improved efficiency, a parallel plate capacitive coupler 20 (or the examples of FIGS. 5 and/or 6) may be the better choice.

In other examples, high-power laser device 14 may be used, for example, in laser tools (e.g., for cutting or burning), laser-based defense apparatus using high power (e.g., for air defense), or long-distance power transmission (e.g., for space-based applications). Such lasers may generally be operated in a pulsed fashion; but the pulse rate may generally be below 150 MHz, even as low as 1 kHz or less. In such cases, the parallel concentric coil capacitive element 15 may be the better choice (except in cases where the pulse rate may exceed 150 MHz, in which case the example of FIG. 5 below may be more effective).

FIGS. 5 and 6 present example alternatives for use with input signal frequencies exceeding 150 MHz. In the alternative of FIG. 5, the parallel coil capacitive element concept, as in previous examples, may continue to be used; however, as frequency increases beyond about 150 MHz the wire coils used in previous examples may become self-inductive, leading to mismatch and power loss. Therefore, according to the example of FIG. 5, the wire coils may be replaced with coiled conductive plates, which may be used for both inner coil 12 and outer coil 11. The conductive plates may be formed of a conductive material, such as, but not limited to, copper, silver, or gold or a silver- or gold-plated material. If the conductive plates are coated with an insulator, they may be tightly wound, similarly to the case of wire coils. However, this may not be the case, meaning that the coils may need to be separated from one another, either by not being tightly wound (which may work for higher frequency signals) or by a helical projection formed of an insulating material on or as part of the tube around which the conductive plate is coiled or some similar structure composed of an insulating material, e.g., ceramic, on or as part of the tube (as in the case of the coils above, the tube itself may be composed of an insulating material, such as but not limited to a ceramic). In this case of needing to separate the coils, the conductive plate may be wound within the helical projection/between insulating structures (not shown) such that the helical projection/structure(s) separates adjacent coils of the conductive plate. The helical projection or structure(s) may or may not be continuous, i.e., there may be gaps between sections, and the sections may be of arbitrary size(s). The coils 11, 12 may be connected as in any of the previous examples using parallel coil capacitive elements.

When the input signal frequency exceeds approximately 750 MHz, the example of FIG. 6 may provide improved performance over the example of FIG. 5. The structure of FIG. 6 may be of a chip size, e.g., even as small as 1 mm×1 mm. The structures 60, 61a, 61b, 63 shown in FIG. 6 may be formed within/surrounded by non-conductive, non-magnetic material within a chip-like package. If the frequencies for which the structures are designed is around 750 MHz, the package may be about one inch long; but as the frequencies for which the structure is designed increase, the structure size/package size may be smaller. Structure 63 may correspond to the inner (primary) coil of the previous examples and may be formed of a coiled conductive plate, as in the example of FIG. 5, which may be composed of, for example, but not limited to, copper, silver, or gold; however, structure 63 may be formed as a “wavy plate,” rather than as a coil around a tube. It is noted that other shapes may be used, as long as the resulting impedances are properly matched to the amplifier and to the laser device. These plate shapes may be one-dimensional and may form any shapes as long as they are designed to match the laser device input impedance. The primary shape may be disposed on one side of a circuit board and the other secondary shape may be disposed on the opposite side of the circuit board. Structure 63 may be connected, as in the previous examples, between the (amplified) input signal and ground or DC. Components 60, 61a, 61b may be conductive plates of various sizes and/or shapes, which may be composed of the same material as the structure 63. Plate 60 may be of a length approximately equal to the length of structure 63. Plates 61a, 61b may typically be much smaller, as shown in FIG. 6. These plates 61a, 61b may, in combination with structure 63, form capacitors. According to a further aspect of the present disclosure, plates 61a, 61b may be replaced by a capacitor 62 whose output is directed into the laser device (not shown). In general, the higher the frequency of intended use, the smaller the structures 60, 61a, 61b, 63 may be made.

It is noted that the example of FIG. 4 may be adapted to include three different capacitive coupling structures that are optimized for three different frequency ranges and to use three-way switches controlled by a control signal that may be generated by control logic based on a frequency range of the input signal to the capacitive structures (i.e., to the switches). The control logic in this case may comprise multiple comparator elements or alternatively a frequency/amplitude detector. In further examples, this may be extended beyond three capacitive elements.

In general, the dimensions of the various components of the capacitive elements shown in the drawings and described above may take various dimensions, which may be determined based on use cases, which may, in particular, correspond to the power and frequency of intended use. Higher power and/or lower frequency may generally indicate the use of larger components, and vice versa. One skilled in the art would be capable of recognizing different scenarios in which different component sizes may be used and would be able to adapt the different components using, e.g., principles of physics.

Additionally, various parameters, such as numbers of windings may generally depend on a frequency/pulse rate of the input signal, as would be apparent to one skilled in the art. It is noted that wire thickness and length may depend upon how high the desired laser output power is intended to be. In an illustrative example, to which the invention is not limited, to achieve laser output power on the order of about 100 kW, copper wires of a few inches in diameter may be used in coils 11, 12. Variable capacitor 13 may need to be a few feet long to isolate a high voltage and withstand a high current level, in particular during startup, when voltage is initially applied and the input impedance of the tube amplifier 141 of the high-power laser device 14 is on the order of hundreds of ohms. After the tube amplifier 141 turns on, there may be, for example, around 450 V, along with 450 A of current (that may be used to generate laser output power around 100 kW), while the tube amplifier 141 input impedance drops to a much lower value, as discussed above.

Various aspects of the disclosure have been presented above. However, the invention is not intended to be limited to the specific aspects presented above, which have been presented for purposes of illustration. Rather, the invention extends to functional equivalents as would be within the scope of the appended claims. Those skilled in the art, having the benefit of the teachings of this specification, may make numerous modifications without departing from the scope and spirit of the invention in its various aspects.

What is claimed is:

1. A high-power laser system including:
a capacitive coupling device coupled between an input signal and an input to a high-power laser device, the coupling device including:
a first fixed capacitive element; and
a tuning capacitive element, comprising a variable capacitive element or a second fixed capacitive element distinct from the first fixed capacitive element,
wherein the tuning capacitive element is configured to cause the coupling device to substantially match an input impedance of the high-power laser device, and
wherein an input impedance of the coupling device is configured to match an output impedance of a component providing the input signal.

2. The system of claim 1, further including an amplifier arranged to amplify the input signal and coupled to provide an amplified version of the input signal as the input to the capacitive coupling device.

3. The system of claim 1, wherein the high-power laser device comprises a closed-tube chamber amplification laser device.

4. The system of claim 3, wherein the closed-tube chamber amplification laser device includes a tube-type amplifier coupled to receive an output signal from the capacitive coupling device and to provide an output signal arranged to excite a laser medium or coupled to a device to excite a laser medium, wherein the tube-type amplifier and the laser medium are contained withing a common housing.

5. The system of claim 4, wherein the device to excite the laser medium comprises a pumping lamp, and the resulting laser is a lamp-pumped laser.

6. The system of claim 1, wherein the high-power laser device comprises:
a tube-type amplifier coupled to receive an output signal from the capacitive coupling device and to provide an amplified output signal; and
a laser device coupled to receive the amplified output signal and to generate a laser output.

7. The system of claim 1, wherein the first fixed capacitive element comprises a pair of parallel concentric coils, wherein the input signal is arranged to be coupled to a first one of the pair of coils, and wherein a second one of the pair of coils is arranged to provide an output signal to the variable capacitive element or the second fixed capacitive element.

8. The system of claim 7, wherein each of the parallel concentric coils comprises wire wound around a respective non-conductive, non-magnetic tubular core with substantially no space between windings within a coil.

9. The system of claim 7, wherein the first fixed capacitive element further comprises a dielectric disposed between the pair of parallel concentric coils.

10. The system of claim 9, wherein the dielectric is air.

11. The system of claim 7, wherein the coils of the respective concentric parallel coils comprise conductive plates wound around respective non-conductive, non-magnetic tubular cores.

12. The system of claim 1, wherein the first fixed capacitive element comprises a pair of parallel conductive plates, wherein a first one of the plates is arranged to be coupled to the input signal, and wherein a second one of the plates is arranged to provide an output signal to the variable capacitive element or the second fixed capacitive element.

13. The system of claim 12, wherein the first fixed capacitive element further comprises a dielectric disposed between the pair of parallel conductive plates.

14. The system of claim 13, wherein the dielectric is air.

15. The system of claim 12, wherein the second one of the plates has an arbitrary shape such that it serves to substantially match the input impedance of the high-power laser device.

16. The system of claim 1, wherein the variable capacitive element is arranged to be adjusted automatically.

17. The system of claim 1, wherein the first fixed capacitive element comprises:
a first capacitive element and a second capacitive element,
wherein the first capacitive element comprises a pair of parallel concentric coils, wherein the coils are formed of conductive plates, wherein the input signal is arranged to be coupled to a first one of the pair of coils, and wherein a second one of the pair of coils is arranged to provide an output signal to the variable capacitor, and
wherein the second capacitive element comprises a pair of parallel conductive plates, wherein a first one of the plates is arranged to be coupled to the input signal, and wherein a second one of the plates is arranged to provide an output signal to the variable capacitive element or the second fixed capacitive element;
a first switch coupled to receive the input signal and to route it to either the first capacitive element or the second capacitive element; and
a second switch coupled to receive an output from the first capacitive element or the second capacitive element and to provide an output signal to the variable capacitive element or the second fixed capacitive element.

18. The system of claim 17, further including:
a frequency detector coupled to receive as an input the input signal, to detect a frequency or frequency range of the input signal, and to output a signal indicative of the detected frequency or frequency range of the input signal; and
control logic including at least one comparator, the control logic coupled to receive the signal indicative of the detected frequency or frequency range and arranged to generate a control signal coupled to control the first and second switches.

19. The system of claim 17, further including:
a frequency/amplitude detector coupled to receive as an input the input signal, to detect at least an amplitude of the signal, and to output a signal indicative of the amplitude of the input signal; and
control logic including at least one comparator, the control logic coupled to receive the signal indicative of the detected amplitude of the input signal and arranged to generate a control signal coupled to control the first and second switches.

20. The system of claim 1, wherein the variable capacitive element comprises:
a first capacitive element having a first impedance;
a second capacitive element having a second impedance different from the first impedance;
a first switch to direct a signal input to the variable capacitive element to either the first capacitive element or the second capacitive element; and
a second switch, controlled in parallel with the first switch, to select as an output of the variable capacitive element an output of the one of the first capacitive element or the second capacitive element to which the signal is directed by the first switch.

21. The system of claim 1, wherein a structure of the first fixed capacitive element, a structure of the tuning capacitive element, or both the structure of the first fixed capacitive element and the structure of the tuning capacitive element is or are formed to permit flow of a cooling medium through and/or around the structure of the first fixed capacitive element, the structure of the tuning capacitive element, or both the structure of the first fixed capacitive element and the tuning capacitive element.
